(19) United States
(12) Patent Application Publication
(10) Pub. No.: US 2009/0251218 A1
(43) Pub. Date: Oct. 8, 2009

(54) Variable Gain Amplifier

(76) Inventor: Paulo Oliveira, Neubiberg (DE)

Correspondence Address: SLATER & MATSIL LLP, 17950 PRESTON ROAD, SUITE 1000, DALLAS, TX, 75252, US

(21) Appl. No.: 12/062,438

(22) Filed: Apr. 3, 2008

(51) Int. Cl. H03G 3/00

(52) U.S. Cl. 330/278

(57) ABSTRACT

A variable gain amplifier for amplifying an amplifier input signal includes a current steering transconductance stage and an impedance transformation network configured to match the current steering transconductance stage to the amplifier output. The impedance transformation network includes a tapped inductor, wherein a first inductive portion of the tapped inductor is magnetically coupled with a second inductive portion of the tapped inductor. The current steering transconductance stage is configured to receive the amplifier input signal and to controllably provide a current signal to a node at the first end of the inductor or to a node electrically circuited between the amplifier output and the first end of the inductor, or to a first tap of the tapped inductor, or to a second tap of the tapped inductor.

### BACKGROUND

Some embodiments according to the invention are related to a variable gain amplifier. Some embodiments according to the invention are related to a tapped load inductor gain-control technique for low-noise high-frequency amplifiers.

In the following, some examples of possible applications for variable gain amplifiers will be described.

Some signal processing systems require interfaces to the analog world. Examples of theses interfaces are the transmission media for wired or wireless communication. A possible receiver architecture includes a low-noise high-frequency amplifier (LNA) followed by a mixer. The purpose of the LNA (or at least one possible effect thereof) may be to increase the signal power which can be passed on to a subsequent stage, for example, in order to make a further signal processing insensitive (or less sensitive) to noise, and/or to achieve a minimum (or a reduced) signal-to-noise ratio (SNR) degradation. The mixer may, for example, shift the received signal down to a lower frequency, where filtering and processing may be more readily accomplished.

At a mixer output, a certain minimum SNR may be required to demodulate an incoming signal. The weaker the received signal at the LNA input, the more amplification may be required in the LNA to establish the desired SNR at the mixer output. On the other hand, driving the mixer at an excessive level with a strong received signal may cause distortion that also reduces the SNR. Thus, for any given received signal level, there may exist one optimum LNA gain that may (at least approximately) maximize the SNR at the mixer output.

To cope with some or all of these demands, variable-gain low-noise high-frequency amplifiers (VGAs) may be useful. VGAs may be used in numerous electronic products such as global positioning (GPS) receivers, wireless local area networks (WLAN) and mobile communication devices, such as cordless and cellular phones.

LNAs with two different gain settings may be used in receiver architectures. A high-gain setting may be used with weak incoming signals, and a low-gain setting may be used with strong incoming signals. Such LNAs may be well suited for digital control and may provide adequate performance if only a wanted signal is present.

Some wireless applications, such as mobile phones, may in some cases need to be capable of receiving a weak base station signal in the presence of strong adjacent channels from other base stations. As the adjacent channels may be in the same frequency band as the wanted signal, they cannot be filtered out before the mixer in some cases. Just like a strong wanted channel, a strong adjacent channel may overload the mixer if the LNA gain is too high. This may sometimes spread energy from the adjacent channel into the wanted channel, thus decreasing the SNR of the wanted channel. Thus, there may be some conditions where the LNA gain should be reduced somewhat to avoid overloading the mixer with a strong adjacent channel, but yet should still be adequate to maximize the SNR for a much weaker wanted signal. Thus, in some cases it may be desirable to have a higher number of gain settings. For example, for many mobile data applications, such as wide band code division multiple access (W-CDMA) high speed downlink packet access (HSDPA), adding a third (for example, mid-) gain step may be sufficient.

### SUMMARY OF THE INVENTION

Some embodiments according to the invention provide a variable gain amplifier for amplifying an amplifier input signal, to obtain an amplifier output signal at an amplifier output.

An amplifier according to an embodiment of the invention may comprise a current steering transconductance stage and an impedance transformation network configured to match the current steering transconductance stage to the amplifier output. The impedance transformation network may comprise a tapped inductor. The tapped inductor may comprise a first inductive portion electrically between the first end of the inductor and a tap of the inductor and a second inductive portion electrically between the tap and a second end of the inductor. The first inductive portion is magnetically coupled with the second inductive portion. The current steering transconductance stage may be configured to receive the amplifier input signal, to controllably provide a first current signal to a node at the first end of the inductor or to a node electrically circuited between the amplifier output and the first end of the inductor, and to controllably provide a second current signal to the tap of the inductor. The first current signal and the second current signal may be based on the amplifier input signal. The current steering transconductance stage may be configured to allow for an adjustment of a ratio of amplitudes of the first current signal and of the second current signal, to allow for an adjustment of a gain.

In another embodiment according to the invention, the tapped inductor may comprise a first inductive portion electrically between a first end of the tapped inductor and a first tap of the inductor, a second inductive portion electrically between the first tap of the inductor and a second tap of the inductor, and a third inductive portion electrically between the second tap of the inductor and a second end of the inductor. At least two of the inductive portions are magnetically coupled. The current steering transconductance stage may be configured to receive the amplifier input signal, to controllably provide a first current signal to the first tap of the inductor, and to controllably provide a second current signal to the second tap of the inductor. The first current signal and the second current signal may be based on the amplifier input signal. The current steering transconductance stage may be configured to allow for an adjustment of a ratio of amplitudes of the first current signal and the second current signal to allow for an adjustment of a gain.

Another embodiment according to the invention creates a variable gain amplifier for amplifying an amplifier input signal. The amplifier may comprise a current-steering transconductance stage comprising a transconductance device. The transconductance device may be configured to control a current flowing via a main current path in dependence on the amplifier input signal. The amplifier may also comprise an impedance transformation network configured to match an impedance of the transconductance device to an output impedance of the variable gain amplifier. The impedance transformation network may comprise a tapped inductor, wherein the tapped inductor may comprise a first inductive portion electrically between a first end of the tapped inductor and a tap of the tapped inductor, and a second inductive portion electrically between the tap and a second end of the tapped inductor. The first inductive portion may be magnetically coupled with the second inductive portion. The current-steering transconductance stage may be configured to selectively couple a main current path of the transconductance device to the tap or to another node of the tapped inductor, to allow for a control of a gain of the variable gain amplifier.

### BRIEF DESCRIPTION OF THE DRAWINGS

Embodiments according to the invention will subsequently be described with reference to the enclosed figures, in which:

FIG. 1a shows a block schematic diagram of a variable gain amplifier, according to an embodiment according to the invention;

FIG. 1b shows a block schematic diagram of a variable gain amplifier, according to an embodiment according to the invention;

FIG. 2 shows a block schematic diagram of a variable gain amplifier, according to an embodiment according to the invention;

FIG. 3 shows a schematic diagram of a variable gain amplifier, according to an embodiment according to the invention;

FIG. 4 shows a schematic diagram of a current-steering transconductance amplifier, according to an embodiment according to the invention;

FIG. 5 shows a schematic diagram of a current-steering transconductance amplifier, according to an embodiment according to the invention;

FIG. 6 shows a schematic diagram of a tapped inductor for use in an embodiment according to the invention;

FIGS. 7a to 7e show schematic representations of tapped inductors for use in embodiments according to the invention; and

FIG. 8 shows a flowchart of a method for operating a variable gain amplifier.

### DETAILED DESCRIPTION OF ILLUSTRATIVE EMBODIMENTS

### First Embodiment

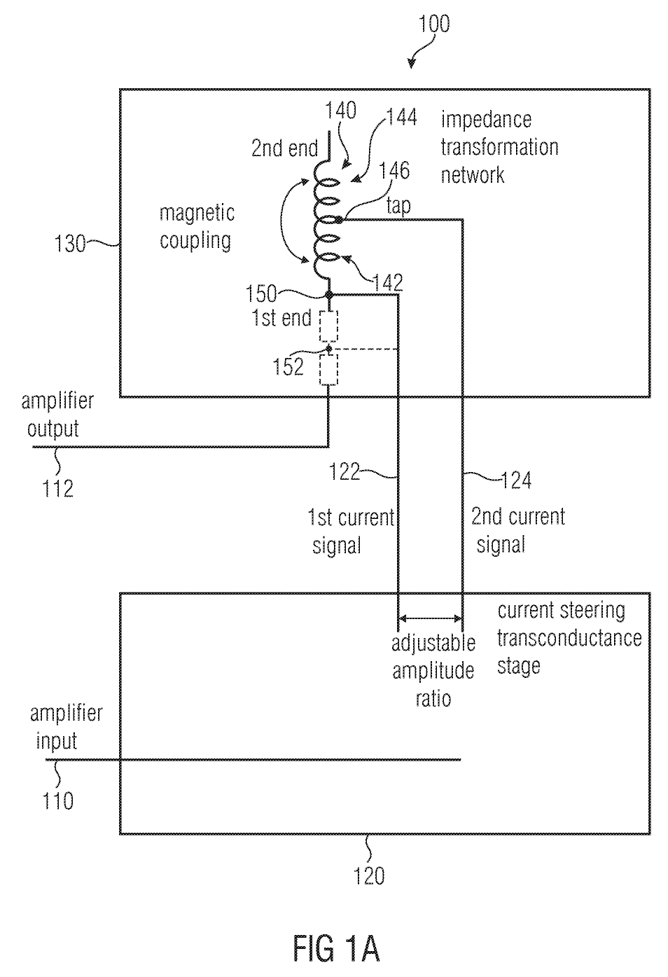

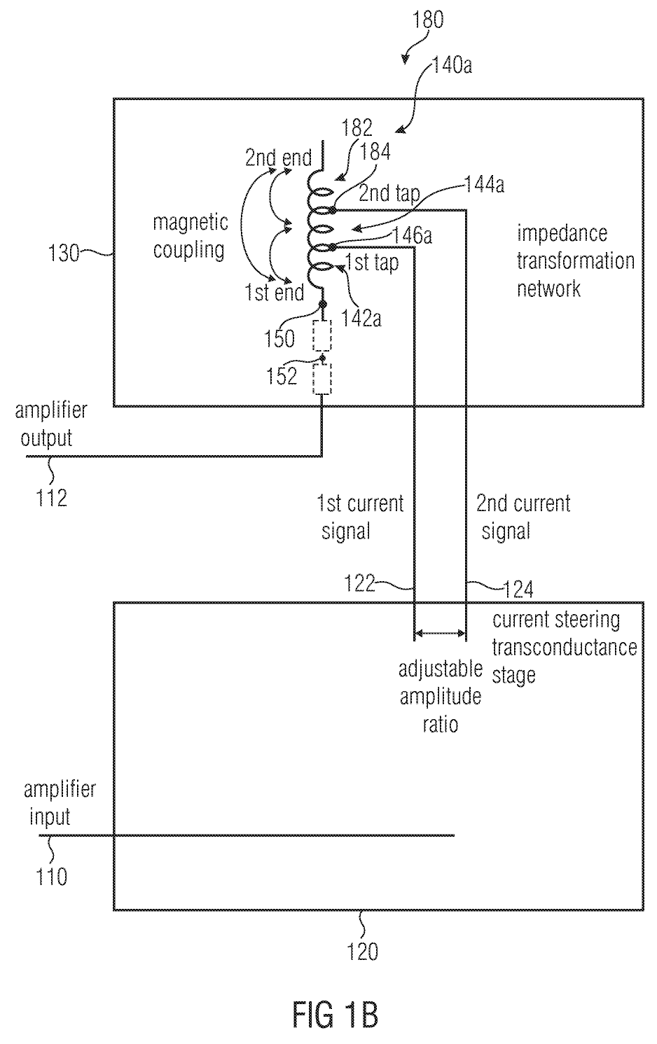

FIG. 1a shows a block schematic diagram of a variable gain amplifier according to an embodiment according to the invention. The variable gain amplifier shown in FIG. 1a is designated in its entirety with 100. The variable gain amplifier 100 comprises an amplifier input 110 for receiving an amplifier input signal and an amplifier output 112 for providing an amplifier output signal. The variable gain amplifier 100 comprises a current-steering transconductance stage 120 and an impedance transformation network 130. The current-steering transconductance stage 120 is configured to receive the amplifier input signal from the amplifier input 110 and to provide, on the basis of the amplifier input signal, a first current signal 122 and a second current signal 124 to the impedance transformation network 130. The impedance transformation network 130 is configured to match the current-steering transconductance stage 120 to the amplifier output, such that the amplifier output signal 112 is generated on the basis of the current signals 122, 124.

The impedance transformation network 130 comprises a tapped inductor 140. The tapped inductor 140 comprises a first inductive portion 142 and a second inductive portion 144. The first inductive portion 142 is arranged electrically between a first end of the inductor and a tap 146 of the inductor. The second inductive portion 144 is arranged electrically between the tap 146 and a second end of the inductor 140. The first inductive portion 142 is magnetically coupled with the second inductive portion 144.

The current-steering transconductance stage 120 is configured to controllably provide the first current signal 122 to a node at the first end 150 of the inductor 140 or to a node electrically circuited between the amplifier output 112 and the first end 150 of the inductor 140. In addition, the current-steering transconductance stage 120 is configured to controllably provide the second current signal 124 to the tap 146 of the inductor 140. Also, the current-steering transconductance stage 120 is configured to allow for an adjustment of a ratio of amplitudes of the first current signal 122 and of the second current signal 124, to allow for an adjustment of a gain of the variable gain amplifier 100.

In the following, the functionality of the variable gain amplifier 100 will be described in more detail.

In the circuit shown in FIG. 1a, the inductor 140 may be configured to act as a matching device of the impedance transformation network 130. However, the gain of the amplifier 100 may be dependent on a position where a current signal is coupled to the impedance transformation network.

In a first gain state, a current signal from the current-steering transconductance stage 120 may be fed into the impedance transformation network 130 at the first end 150 of the inductor 140 or at a node 152 electrically arranged between the amplifier output 112 and the first end 150 of the inductor 140. As can be seen, it is assumed here that the first end 150 of the inductor 140 is coupled directly or via one or more additional elements (like, for example, resistors, capacitors, inductors or other lumped or distributed circuit elements) with the amplifier output. In this case, the main current path from the current-steering transconductance stage 120 to the amplifier output 112 will extend via a signal path of the first current signal 122, via a node at the first end 150 of the inductor 140 (or, alternatively, via the node 152 between the amplifier output 112 and the first end 150 of the inductor 140) to the amplifier output 112. In this case, the main output current path from the current-steering transconductance stage 120 to the amplifier output 112 will avoid the inductor 140. However, the inductor 140 will be efficient as a matching element. For example, the inductive impedance of the inductor 140 will be effective to determine a voltage gain or power gain of the amplifier 100. Simply speaking, the inductor 140 may be effective to translate the current of the first current signal 122 into a voltage at the first end 150 of the inductor 140. Thus, for a given current amplitude of the first current signal 122, the resulting voltage at the amplifier output 112 is effected by the effect of the inductance 140. To summarize the above, a dominant portion of the current provided to the impedance transformation network 130 by the current-steering transconductance stage 120 is provided via the signal path of the first current signal 122. The full inductance 140 may be efficient as a load impedance. Accordingly, a relatively high amplification of the overall amplifier 100 can be obtained.

In contrast, in a second gain state, a dominant portion of the current provided to the impedance transformation network by the current-steering transconductance stage 120 may be provided via a signal path of the second current signal 124. In other words, a dominant portion of the current provided by the current-steering transconductance stage to the impedance transformation network 130 may be fed to the tap 146 of the inductor 140. Accordingly, only a part of the total inductance of the inductor 140 is effective as a load inductance for the current-steering transconductance stage 120. Thus, a gain (for example, a voltage gain or a power gain) of the amplifier 100 is smaller in the case where a dominant portion of the current is provided via the signal path of the second current signal, when compared to a case in which a dominant portion of the current is provided via a signal path of the first current signal. It should be noted here that in the second case, in which the dominant portion of the current is provided via the signal path of the second current signal, a main output current path extends from the current-steering transconductance stage 120 via the signal path of the second current signal 124, via tap 146 and via the first end 150 of the inductor 140 to the amplifier output 112. However, a portion of the current provided via the signal path of the second current signal 124 may also flow towards the second end of the inductor 140.

To summarize the above, a first gain state of the amplifier 100 with a comparatively high gain can be obtained if a dominant portion of the current is provided from the current-steering transconductance stage 120 via the signal path of the first current signal 122. A second gain state with a comparatively low gain can be obtained if a dominant portion of the current is provided by the current-steering transconductance stage 120 via the signal path of the second current signal 124. Thus, the gain of the amplifier 100 can be adjusted by adjusting an amplitude ratio of the first current signal 122 and the second current signal 124.

However, it should be noted that sometimes there is a need for a particularly cost-efficient and/or space-efficient implementation of a variable current amplifier. In some other cases, it may be desirable to provide an amplifier with a well-defined ratio of amplifications in different states. In some cases it may also be desirable to minimize a component count. Moreover, in some cases it may be desirable to have more than two gain states or gain steps. Moreover, in some cases it may be desirable to simplify a design rule for adjusting an amplification of the amplifier 100.

In some embodiments, the usage of the inductor 140 having at least two magnetically coupled inductive portions 142, 144 may bring along a reduction of a size of the amplifier 100. For example, in some embodiments the magnetic coupling between the first inductive portion 142 and the second inductive portion 144 may have the effect that the inductor 140 provides the desired impedance in a particularly efficient way. Thus, in some embodiments the inductor 140 can be implemented in a particularly space-efficient way, for example, when compared to solutions in which the first inductive portion 142 and the second inductive portion 144 would be implemented by separate discrete components or inductors. In some cases, the space-efficient implementation of the inductor 140 may bring along cost reductions, as costs for the production of a circuit are typically affected by the amount of space required.

In some embodiments, the usage of the inductor 140 having two magnetically coupled inductive portions 142, 144 may make the amplifier 100 particularly well-suited for a monolithic integration. Also, in some cases it may be easily possible to monolithically integrate the inductor 140 on a semiconductor substrate with very high precision, such that overall system costs can be reduced due to the monolithic integration. In some embodiments a high precision of the amplifier gain can be achieved, for example, by defining the dimensions of the inductor 140 using a lithographic process.

It should be noted here that the circuit shown in FIG. 1a can be implemented in many ways. For example, the amplifier 100 can be extended to more than two gain steps or gain states. For example, the inductor 140 can be supplemented by one or more additional taps, to which further current signals may be provided by an extended current-steering transconductance stage. Also, one or more additional matching components can be added to the circuit. For example, one or more resistive or reactive components can be circuited between the amplifier output and the first end 150 of the inductor 140, as indicated in FIG. 1a. Also, the position where the first current signal 122 is fed can be modified. As indicated in FIG. 1a, the first current signal 122 can be fed to a node at the first end 150 of the inductor 140. However, in the alternative embodiment the first current signal 122 can be supplied to a circuit node which is electrically circuited between the amplifier output 112 and the first end 150 of the inductor 140. While FIG. 1a shows a case in which the first current signal 122 and the second current signal 124 are provided directly to the respective nodes (for example, to the first end 150 of the inductor 140, to the node 152 arranged electrically between the amplifier output 112 and the first end 150 of the inductor, or to the tap 146), one or more additional circuit elements (for example, resistors and/or inductors and/or capacitors) can be circuited between the current paths of the first current signal or of the second current signal and the nodes. For example, if a DC decoupling is desired, the first current signal 122 and the second current signal 124 can be provided to the respective nodes via respective capacitors. Also, one or more inductors or resistors or switches may in some embodiments be circuited between the signal paths of the first and second current signal 122, 124 and the respective nodes of the impedance transformation network, where the first and second current signal are provided.

Moreover, it should be noted here that different alternatives are possible for the generation of the first current signal 122, as will be explained later on. In some embodiments only one of the first and second current signals 122, 124 is active at a given gain state. However, in some other embodiments both the first current signal 122 and the second current signal 124 may be active at the same gain state. In this case, the first and second current signals 122, 124 may have identical or different amplitudes.

### Second Embodiment

In the following, another possible circuit configuration will be described with reference to FIG. 1b. FIG. 1b shows a block schematic diagram of an amplifier according to another embodiment according to the invention. The amplifier shown in FIG. 1b is designated in its entirety with 180. It should be noted here that identical means and signals are designated with identical reference numerals in FIGS. 1a and 1b. In contrast, elements which are slightly modified are designated with identical numbers, wherein a “a” is added to the reference numeral to indicate the modification.

The embodiment shown in FIG. 1b differs from the embodiment shown in FIG. 1a with respect to the configuration of the inductor 140 and with respect to the locations at which the current signals are provided to the impedance transformation network. Taking reference to FIGS. 1a and 1b, the inductor 140 of the amplifier 100 is replaced by the inductor 140a in the amplifier 180 of FIG. 1b. The inductor 140a comprises a first inductive portion 142a, a second inductive portion 144a and a third inductive portion 182. The first inductive portion 142a is electrically arranged between a first end 150 of the inductor 140a and a first tap 146a of the inductor 140a. The second inductive portion 144a is circuited between the first tap 146a and a second tap 184. The third inductive portion 182 is arranged electrically between the second tap 184 and a second end of the inductor 140a.

In an embodiment, at least two of the inductive portions 142a, 144a, 182 are magnetically coupled. In some embodiments, there may even be a magnetic coupling between any two inductive portions of the inductor 140a. For example, there may be a magnetic coupling between the first inductive portion 142a and the second inductive portion 144a, a magnetic coupling between the second inductive portion 144a and the third inductive portion 182, and a magnetic coupling between the first inductive portion 142a and the third inductive portion 182.

The amplifier 180 shown in FIG. 1b also differs from the amplifier 100 shown in FIG. 1a in that both the first current signal 122 and the second current signal 124 are provided to the taps 146a, 184 of the inductor 140a. For example, the first current signal 122 is provided to the first tap 146a, and the second current signal 124 is provided to the second tap 184 of the inductor 140a.

Regarding the operation of amplifier 180, it should be noted that the operation is similar to the operation of the amplifier 100.

For example, if a dominant portion of the current provided by the current-steering transconductance stage 120 to the impedance transformation network 130 is provided via the signal path of the first current signal 122, a main output current path extends from the current-steering transconductance stage 120 to the amplifier output 112 via the signal path of the first current signal, the first tap 146a and the first end of the inductor 140a. Thus, an impedance of the second inductive portion 144a and of the third inductive portion 182 is effective for determining a gain of the amplifier 180 in this case.

If a dominant portion of the current provided by the current-steering transconductance stage 120 to the impedance transformation network 130 is provided via the signal path of the second current signal 124, a main output current path from the current-steering transconductance stage 120 to the amplifier output 112 extends via the signal path of the second current signal, the second tap 184 and the first end 150 of the inductor 140a. In this case, the third inductive portion 182 (or an impedance thereof) may be effective to determine a gain of the amplifier 180.

Thus, a first gain or gain state of the amplifier 180 can be achieved by providing a dominant portion of the current from the current-steering transconductance stage 120 to the impedance transformation network 130 via the signal path of the first current signal 122. A second gain or gain state can be achieved by providing a dominant portion of the current from the current-steering transconductance stage 120 to the impedance transformation network 130 via the signal path of the second current signal 124. In other words, in some embodiments a gain of the amplifier 180 can be adjusted by deciding whether the current from the current-steering transconductance stage 120 is provided to the first tap 146a of the inductor 140a or to the second tap 184 of the inductor 140a. Thus, by controlling to which of the taps 146a, 184 of the inductor 140a the dominant portion of the current (or all of the current) is provided, the gain of the amplifier can be adjusted or controlled.

To summarize the above, by controlling a main current from the current-steering transconductance stage 120 to the impedance transformation network 130, the gain of the amplifier 100 and the gain of the amplifier 180 can be adjusted. In both cases, the tapped inductor having magnetically coupled inductive portions may in some embodiments provide the possibility to reduce a size of the inductor 140, 140a, to reduce production costs, to increase a gain accuracy and/or to facilitate a circuit design.

### Third Embodiment

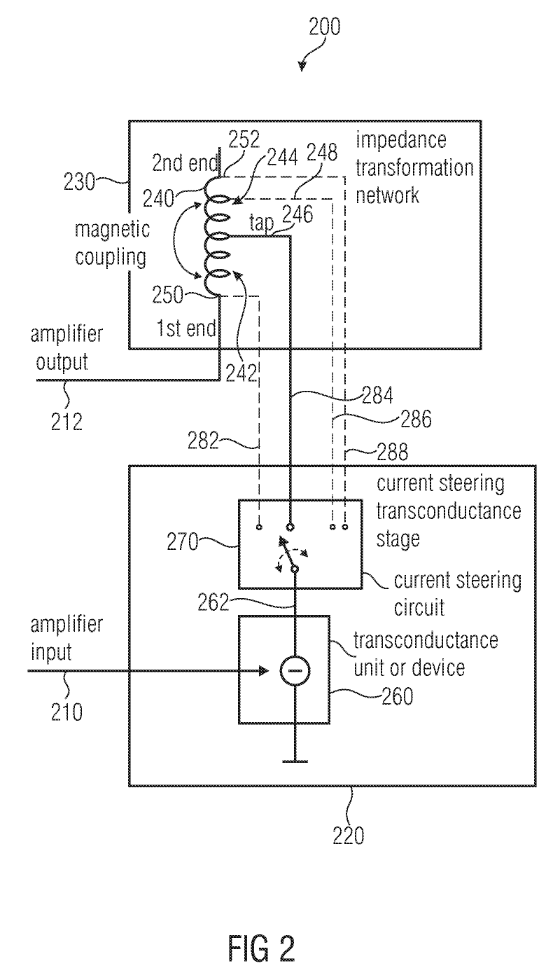

In the following, another embodiment according to the invention will be described taking reference to FIG. 2. FIG. 2a shows a block schematic diagram of an amplifier according to an embodiment. The amplifier shown in FIG. 2 is designated in its entirety with 200. The amplifier 200 comprises an amplifier input 210, which may be equivalent to the amplifier input 110, and an amplifier output 212, which may be equivalent to the amplifier output 112. The amplifier 200 also comprises a current-steering transconductance stage 220, which may be equivalent to the current-steering transconductance stage 120. The amplifier 200 further comprises an impedance transformation network 230, which may be equivalent to the impedance transformation network 130. The impedance transformation network 230 may comprise a tapped inductor 240, which may be similar to the tapped inductor 140. The tapped inductor 240 may, for example, comprise a plurality of magnetically coupled inductive portions 242, 244, wherein a tap 246 (which may be similar to the tap 146) is arranged between two of the magnetically coupled inductive portions 242, 244.

The current-steering transconductance stage 220 may comprise a transconductance unit or transconductance device 260 being configured to receive an amplifier input signal from the amplifier input 210 and to provide a transconductance unit current 262 in dependence on the amplifier input signal. For example, the transconductance unit or transconductance device 260 may be configured to control a current flow via a main current path (for example, of a semiconductor device) in dependence on the amplifier input signal. The current-steering transconductance stage 220 may further comprise a current-steering circuit 270. The current-steering circuit 270 may, for example, be configured to selectively couple a main current path of the transconductance unit or transconductance device 260 to the tap 246 or to another node of the tapped inductor 240, to allow for a control of a gain of the variable gain amplifier 200.

For example, the current-steering circuit 270 may in some embodiments be configured to selectively couple the main current path of the transconductance unit or transconductance device 260 to the first end 250 of the inductor 240 or to the tap 246 of the inductor 240. In this case, signal paths 282, 284 may be available. In an alternative embodiment, the current-steering circuit 270 may be configured to selectively couple the main current path of the transconductance device or transconductance unit 260 to the tap 246 or to another (optional) tap 248. In this case, the signal paths 284, 286 may be present. In another embodiment, the current-steering circuit 270 may be configured to selectively couple the main current path of the transconductance unit or transconductance device 260 to the tap 246 or to the second end 252 of the inductor 240. In this case, the signal paths 284, 288 may be present. To summarize the above, in some embodiments the current-steering circuit 270 may be configured to couple the main current path of the transconductance unit or transconductance device 260 to two different nodes of the tapped inductor 240, wherein a first node is a tap of the tapped inductor, and wherein a second node is an end or a tap of the tapped inductor. Thus, the current-steering circuit may in some embodiments comprise at least two possible settings, and may be configured to select, in dependence on a desired gain, one main current path out of at least two possible main current paths, wherein at least one of the two possible main current paths is routed via a tap of the tapped inductor.

However, it should be noted that in some embodiments, the main current path of the transconductance unit or transconductance device 260 may be selectively coupled to more than two different nodes of the tapped inductor 240. For example, in an embodiment, three or even four of the signal paths 282, 284, 286, 288 may be present. Accordingly, the current-steering circuit 270 may comprise three or four different settings. However, embodiments with even more than four selectable current paths between the current-steering transconductance stage 120 and the impedance transformation network 130 are possible.

Also, in some embodiments the current-steering circuit 270 may be configured to distribute the current provided by the transconductance unit or device 260 to two or more different signal paths 282, 284, 286, 288 (for example, evenly or in a predetermined ratio) for a certain desired gain.

The functionality of the amplifier 200 is similar to the functionality of the amplifiers 100, 180. By selecting the signal paths via which the current provided by the transconductance unit or transconductance device 260 is forwarded to the impedance transformation network 130, or the circuit location where the current from the transconductance unit or transconductance device 260 is injected to the impedance transformation network 130, the effective impedance and the gain of the amplifier 200 can be selected. Thus, a stepwise or gradual selection of the gain is possible.

### Fourth Embodiment

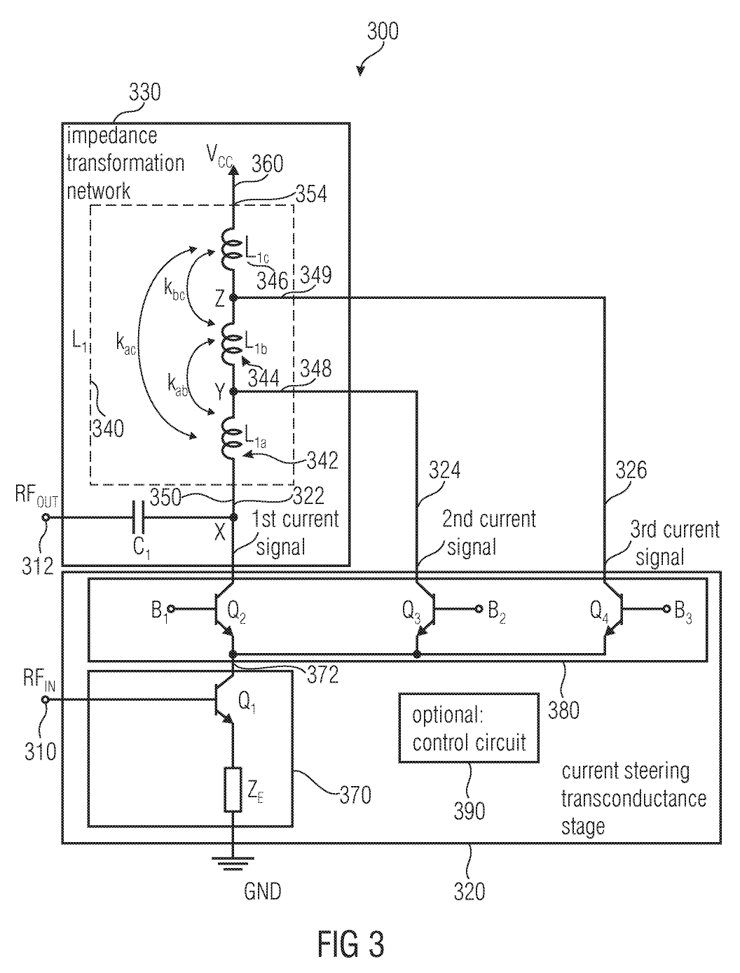

FIG. 3 shows a schematic diagram of a variable gain amplifier, according to an embodiment according to the invention. The amplifier shown in FIG. 3 is designated in its entirety with 300.

The amplifier 300 comprises an amplifier input 310 (also designated as RF_{IN}) and an amplifier output 312 (also designated as RF_{OUT}). The amplifier 300 comprises a current-steering transconductance stage 320 and an impedance transformation network 330. The current-steering transconductance stage 320 is configured to receive the amplifier input signal 310 (which may, for example, be a high-frequency signal or a radio-frequency signal) and to selectively provide three (or, in general, at least two) current signals 322, 324, 326 on the basis of the amplifier input signal 310.

Details regarding the generation of the current signals 322, 324, 326 will be described in detail below.

The impedance transformation network comprises, for example, a tapped inductor 340. The tapped inductor 340 may, for example, be circuited between the amplifier output 312 and a high-frequency-ground node 360. The high-frequency-ground node 360 may, for example, be coupled to a ground potential feed or supply potential feed directly or via a low-impedance element (for example, via a capacitor which acts as a short circuit at an operation frequency). For example, a first end 350 of the inductor (or a node X at the first end 350 of the inductor) may be coupled to the amplifier output 312, either directly or via one or more coupling elements. In the embodiment shown in FIG. 3, the node X at the first end 350 of the tapped inductor 340 is coupled to the amplifier output 312 via a capacitor C₁. Also, in the embodiment shown in FIG. 3, a second end 354 of the inductor (or a node at the second end 354 of the inductor) is coupled to a supply potential V_{CC}, which may, for example, be positive or negative with respect to a ground potential GND. In the embodiment shown in FIG. 3, the supply potential is positive with respect to the ground potential GND.

The tapped inductor 340 comprises, for example, a first inductive portion 342, a second inductive portion 344 and a third inductive portion 346. The inductive portions 342, 344, 346 are circuited between the first end 350 of the inductor 340 and the second end 354 of the inductor 340. The first inductive portion 342 is circuited between the first end 350 of the inductor 340 and a first tap 348. The second inductive portion 344 is circuited between the first tap 348 and a second tap 349. The third inductive portion 346 is circuited between the second tap 349 and the second end 354 of the inductor 340. At least two of the inductive portions 342, 344, 346 are magnetically coupled. The magnetic coupling is indicated by the respective coupling coefficients k_{ab}, k_{bc}, k_{ac}. As can be seen from FIG. 3, the current signals 322, 324, 326 are routed to different nodes of the impedance transformation network 330. For example, the first current signal 322 is routed to the node X. The second current signal 324 is routed to the first tap 348 of the tap inductor 340, i.e., to the node Y. The third current signal 326 is routed to the second tap 349 of the tapped inductor 340, i.e., to the node Z.

Thus, it can be generally the that in the embodiment shown in FIG. 3, one of the current signals, namely the first current signal 322, is routed to a node at the output-sided end of the tapped inductor 340. At least one of the other current signals is routed to a tap of the inductor. However, there are also embodiments in which there are two current signals which are routed to different taps of the tapped inductor, while there may be no current signal routed to the output-sided end of the tapped inductor.

In the following, it will be described how the current signals 322, 324, 326 can be generated. In other words, details of the current-steering transconductance stage 320 will be discussed.

The current-steering transconductance stage 320 comprises a transconductance unit or transconductance device 370. The transconductance unit 370 may, for example, comprise a npn-transistor Q₁. The npn-bipolar transistor Q₁ is configured to receive at its base terminal (either directly or via a coupling or impedance matching network) the amplifier input signal from the amplifier input 310. An emitter terminal of the npn-bipolar transistor Q₁ is, for example, coupled to a reference potential or ground potential GND. For example, the emitter terminal of the transistor Q₁ may be coupled to the reference potential or ground potential via an impedance element Z_{E} or directly. Thus, the transconductance unit 370 may be configured to provide a transconductance unit current signal 372 at a collector terminal of the transistor Q₁ on the basis of the amplifier input signal 310.

The current-steering transconductance stage 320 further comprises a current-steering circuit 380. The current-steering circuit 380 is, for example, configured to receive the transconductance unit current signal 372 and to selectively provide the first current signal 322, the second current signal 324 or the third current signal 326 on the basis of the transconductance unit current signal 372. The current-steering circuit 380 may, for example, comprise a plurality of bipolar transistors Q₂, Q₃, Q₄. As shown in FIG. 3, the current-steering circuit 380 may, for example, comprise three npn-bipolar transistors Q₂, Q₃, Q₄. For example, emitter terminals of the three transistors Q₂, Q₃, Q₄ may be connected. For example, the emitter terminals of the transistors Q₂, Q₃ and Q₄ may all be connected to a collector terminal of the transistor Q₁ of the transconductance unit 370. Thus, the transistors Q₂, Q₃, Q₄ of the current-steering circuit 380 are circuited in a cascode configuration, such that in certain modes of operation, at least one of the transistors Q₂, Q₃, Q₄ provides a low impedance to the collector terminal of the transistor Q₁. The current signal 322, 324, 326 are provided at collector terminals of the transistors Q₂, Q₃, Q₄.

In an embodiment, an optional control circuit 390 may for example be configured to drive the base terminals of the transistors Q₂, Q₃, Q₄ with appropriate control signals. For example, the control circuit 390 may be configured to provide the control signals B₁, B₂, B₃ such that one of the transistors Q₂, Q₃, Q₄ is in a conductive state, while the others of the transistors Q₂, Q₃, Q₄ are in a high impedance state. The control circuit 390 may, for example, be configured to activate (i.e., put into a low-impedance or conducting state) one of the transistors Q₂, Q₃, Q₄ in dependence on a desired gain. For example, if a maximum gain is desired, the optional control circuit 390 may activate (turn on or put into a conductive state) the transistor Q₂, while the transistors Q₃, Q₄ are turned off (or are put into a high impedance state). In contrast, if a medium gain is desired, the optional control circuit may activate the transistor Q₃, while transistors Q₂, Q₄ are deactivated. If a low gain is desired, the optional control circuit 390 may provide such control signals to the base terminals of the transistors Q₂, Q₃, Q₄ that a transistor Q₄ is activated, while the transistors Q₂, Q₃ are deactivated. In other words, the current-steering circuit 380 may, for example, be configured to be controllable (for example, via the control signals B₁, B₂, B₃) to route the transconductance unit current signal 372 to the node X via the signal path of the first current signal 322, or to route the current to the first tap 348 of the tapped inductor 340 via the signal path of the second current signal 324, or to route the current to the second tap 349 of the tapped inductor 340 via the signal path of the third current signal 326, in dependence on the desired gain. In the embodiment shown in FIG. 3, a dominant portion of the transconductance unit current signal 372 is routed via a single one of the signal paths. In other words, a single one of the signal paths of the first current signal 322, of the second current signal 324 and of the third current signal 326 is selected to carry a dominant portion of the current provided by the transconductance unit 370. However, other current distributions may be used. For example, the current provided by the transconductance unit 370 may be split up in portions which may have comparable amplitudes for one or some desired states of the amplifier.

In the following, the structure and the functionality of the amplifier 300 will be briefly summarized. To summarize, FIG. 3 shows a circuit diagram of a gain-control variable gain amplifier (VGA) according to an embodiment of the invention. The transistor Q₁ (which may, for example, be configured as a transconductance unit transistor) forms (or is part of) a common-emitter transconductance stage, eventually degenerated by impedance Z_{E}. Transistors Q₂, Q₃ and Q₄ form (or are part of) a current-steering control circuit 380. The inductor L₁ (also designated with 340) and the capacitor C₁ form an impedance transformation network. The inductor L₁ also serves as a pull-up inductor to increase a headroom at the collectors of the cascode transistors Q₂, Q₃ and Q₄ of the current-steering control circuit. According to an embodiment of the invention, inductor L₁ is tapped, for example, having as many inner connection terminals as the number of gain steps to implement. However, in some embodiments the number of taps may naturally be different from the number of gain steps to be implemented.

In a high-gain mode of the VGA, a voltage at node B₁ (or at a base terminal of the transistor Q₂) may be set to an appropriate bias voltage to render the transistor Q₂ conductive, while voltages at the control nodes B₂ and B₃ (for example, at the base terminals of the transistors Q₃ and Q₄) are set low to turn off the transistors Q₃ and Q₄. The transistor Q₂ may function as a cascode transistor of the transconductance stage (or transconductance unit or transconductance device 370), which output current is then injected into node X (for example, an output-sided node of the inductor 340, or a node between the output-sided end of the inductor 340 and the amplifier output 312). The gain of the VGA is the highest in this mode, because the node X may present a highest load impedance to the transconductance stage 370 (for example, when compared to the nodes Y, Z at the taps of the inductor 340).

A medium-gain mode may, for example, be achieved by setting the bias voltages at nodes B₁ and B₃ low to turn off transistors Q₂ and Q₄, respectively, whereas the voltage at node B₂ is set to an appropriate bias voltage to turn on transistor Q₃, which may now function as a cascode transistor of the transconductance stage 370. The output current is injected into node Y. A gain reduction in this mode, compared to the high-gain mode, may be proportional (or at least approximately proportional) to the ratio (L_{1b}+L_{1c})/(L₁ₐ+L_{1b}+L_{1c}).

In a low-gain mode, the voltages at nodes B₁ and B₂ may be set low to turn off transistors Q₂ and Q₃, respectively, whereas the voltage at node B₃ is set high to turn on transistor Q₄.

An output current of the transconductance stage may be injected into a node Z. A gain reduction in this mode, for example, compared to the high-gain mode, is (at least approximately) proportional to a ratio (L_{1c})/(L₁ₐ+L_{1b}+L_{1c}).

Using this gain-control technique, the output impedance of the low-noise amplifier (LNA) is independent (or only weakly dependent) of the gain modes, because the output impedance is only dependent (or mainly dependent) on the impedance at node X. A noise figure (NF) of the circuit is only degraded by a small amount in the low-gain modes, since no signal current is thrown away.

In some embodiments according to the invention, the impedance transformation network 330 can be designed without using dedicated resistive components. Thus, in some embodiments a limitation of a maximum available gain of the amplifier in a high-gain mode, which may be caused a presence of dedicated resistive elements in the impedance transformation network may be avoided.

For example, in some embodiments according to the invention, the presence of a resistor circuited in parallel with a load can be avoided, whereby a maximum available gain of the amplifier in the high-gain mode can be increased.

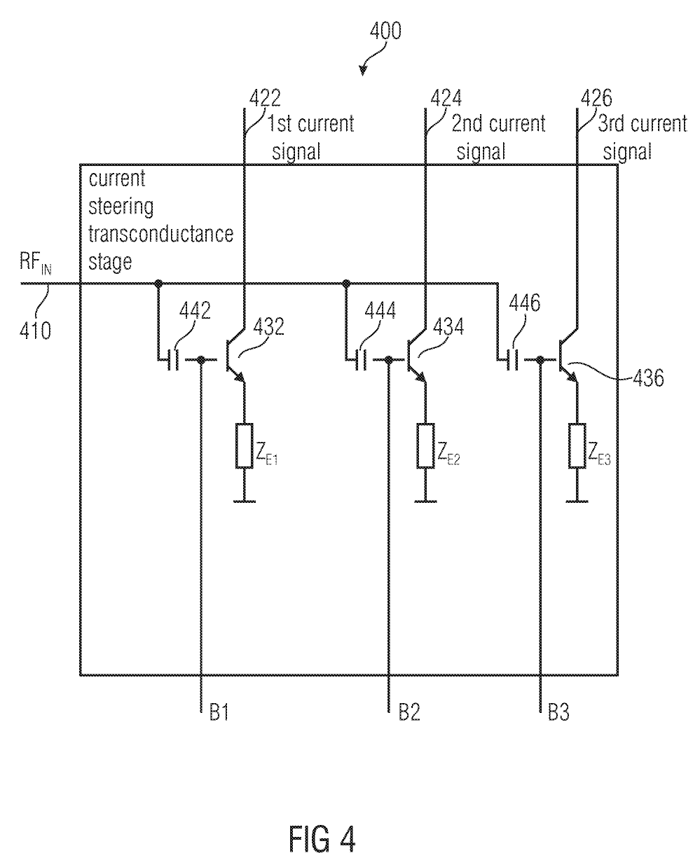

Also, in some embodiments according to the invention, dissipation of power in resistive biasing elements can be avoided or reduced. Also, in some embodiments a voltage-headroom of the cathode-transistors Q₂, Q₃, Q₄ shown in FIG. 3 (or of the amplifier transistors 432, 434, 436 shown in FIG. 4, or of the transistors of the current-steering circuits 532, 534, 536) can be increased or maximized by coupling-collector terminals or drain terminals of the transistors to a bias voltage via taps or end terminals of the tapped inductor. In this case, only the parasitic resistance of the tap is effective, while dedicated resistive circuit elements (for example, in the form of lumped resistors) can be avoided. By increasing the voltage headroom of the transistors, a linearity performance degradation (for example, with respect to compression and intermodulation) in the lower gain modes can be avoided or minimized.

Also, in some embodiments by using a tapped inductor, a size of the circuit can be reduced. In some embodiments, the usage of a single tapped inductor having magnetically coupled inductive portions may contribute to a size reduction. Accordingly, in some embodiments according to the invention a circuit area (for example, a circuit size of an integrated circuit) and circuit costs can be reduced.

While the transconductance device and current-steering switches are illustrated as bipolar transistors in FIG. 3, other suitable devices may be used as well. For example, in some embodiments, field-effect transistors, like, for example, metal-oxide-semiconductor field-effect transistors (MOSFETs) may be used.

Alternative Implementations of the Current-Steering Transconductance Amplifier

In the following, some alternative implementations of the current-steering transconductance stage will be described. FIG. 4 shows a block schematic diagram of a current-steering transconductance stage according to an embodiment according to the invention. The transconductance stage shown in FIG. 4 is designated in its entirety with 400 and may, for example, replace the current-steering transconductance stage 300 shown in FIG. 3. The current-steering transconductance stage 400 comprises an input 410, which may, for example, be equivalent to the signal input 310 shown in FIG. 3. The current-steering transconductance stage 400 may, for example, be configured to selectively provide a first current signal 422, a second current signal 424 and a third current signal 426. The current signals 422, 424, 426 may, for example, be equivalent to the current signals 322, 324, 326. A circuit structure of the current-steering transconductance amplifier 400 can be seen from FIG. 4. For example, the current-steering transconductance amplifier 400 may comprise a plurality of transistors 432, 434, 436. Control terminals (for example, base terminals or gate terminals) of the transistors 432, 434, 436 (which may, for example, be bipolar transistors or field-effect transistors) may, for example, be coupled to the input 410 via capacitors 442, 444, 446. The transistors 432, 434, 436 may, for example, act as switchable amplifiers to provide the current signals 422, 424, 426 on the basis of the input signal or RF input signal from the input 410. For example, the transistors 432, 434, 436 may be activated and deactivated by providing appropriate control signals B1, B2, B3 to their control terminals. In other words, the control terminals of the transistors 432, 434, 436 can be biased in dependence on a desired gain of the overall variable gain amplifier. For example, if a maximum amplification is desired, the first transistor 432 can be activated by providing an appropriate bias signal B1 to the control terminal of the first transistor 432. In this case, the second transistor 434 and the third transistor 436 can be deactivated, by providing appropriate bias signals to the control terminals of the second and third transistor 434, 436.

In contrast, if a medium amplification is desired, the second transistor 434 can be activated by providing an appropriate bias signal to the control terminal of the second transistor 434. In this case, the first transistor 432 and the third transistor 436 may be deactivated.

If a minimum gain is desired, the third transistor 436 can be activated, while the first transistor 432 and the second transistor 434 are deactivated.

Thus, by setting the bias signals at the control terminals of the transistors 432, 434, 436, a distribution of the amplitudes of the current signals 422, 424, 426 can be adjusted. Thus, in some embodiments the current-steering transconductance amplifier 400 shown in FIG. 4 can have a very similar effect when compared to the current-steering transconductance amplifier 320 shown in FIG. 3. In other words, the control signals B1, B2, B3 may have a very similar effect when compared to the control signals B1, B2, B3 of the current-steering transconductance stage 320. As described above, the control signals may be used to determine the distribution of the current amplitudes on the different current signals 422, 424, 426 coupled to different points of the impedance transformation network.

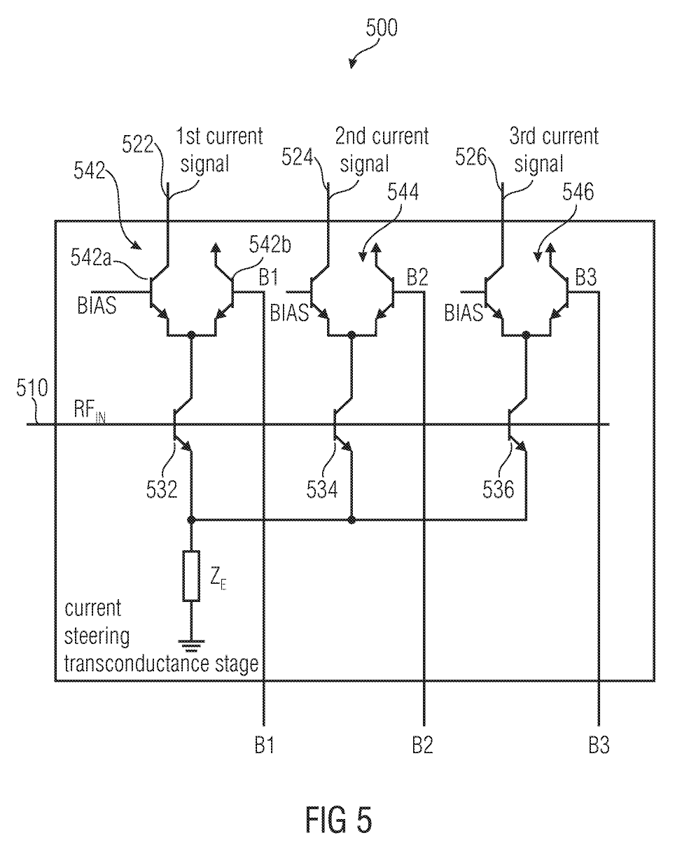

In the following, another configuration of a current-steering transconductance stage will be described with reference to FIG. 5. FIG. 5 shows a block schematic diagram of a current-steering transconductance stage. The current-steering transconductance stage shown in FIG. 5 is designated in its entirety with 500. The current-steering transconductance stage 500 comprises a signal input 510, which may be equivalent to the signal inputs 310, 410 shown in FIGS. 3 and 4.

The current-steering transconductance stage or current-steering transconductance amplifier 500 shown in FIG. 5 may be configured to provide a first current signal 522, a second current signal 524 and a third current signal 526. The current signals 522, 524, 526 may, for example, be equivalent to the current signals 322, 324, 326, 422, 424, 426 described with reference to FIGS. 3 and 4.

The current-steering transconductance stage 500 may, for example, comprise a first amplifier transistor 532, a second amplifier transistor 534 and a third amplifier transistor 536. Control terminals of the amplifier transistors 532, 534, 536 may, for example, be coupled to the signal input 510. Current-steering circuits 542, 544, 546 may, for example, be used to control whether collector currents or drain currents generated by the first transistor 532, the second transistor 534 and the third transistor 536 are used to generate the current signals 522, 524, 526. For example, a first current-routing circuit or current-steering circuit 542 may determine, whether a collector current or drain current generated by the first transistor 532 is used to obtain the first current signal 522. For example, the collector current or drain current of the first amplifier transistor 532 may be steered or routed to a signal path of the first current signal 522, if the transistor 542a is conductive (or switched on) while the transistor 542b is non-conductive (or switched off). In contrast the collector current or drain current of the first amplifier transistor 532 may be dumped, if the transistor 542a is non-conductive (or switched off) and the transistor 542b is conductive (or switched on). Naturally, for the differential-amplifier configuration of the current-routing circuit or current-steering circuit 542, the state (conductive or non-conductive; switched-on or switched-off) of the transistor 542a, 542b can be determined by a control signal B1. Thus, assuming that a control terminal (base terminal or gate terminal) of the transistor 532 is set to a bias potential BIAS, the transistor 542a is switched on and the transistor 542b is switched off if the potential of the control signal B1 is lower than the bias potential BIAS. In contrast, the transistor 542a is switched off and the transistor 542b is switched on if the potential of the control signal B1 is higher (or more positive) than the bias potential BIAS. Thus, the control signal B1 can be used to determine which portion of the collector current or drain current of the first amplifier transistor 532 is coupled to the signal path of the first current signal 522. Similarly, the second current-steering circuit or current-routing circuit 544 can be controlled by the control signal B2. In other words, the control signal B2 can be used to determine which portion of the collector current or drain current of the second amplifier transistor 534 is routed or steered to the signal path of the second current signal 524.

Similarly, the control signal B3 can be used to determine which portion of the collector current or drain current of the third amplifier transistor 536 is routed or steered to the signal path of the third current signal 526.

To summarize the above, a distribution of the amplitudes of the current signals 522, 524, 526 can be determined making use of the control signals B1, B2, B3. Thus, the current-steering transconductance stage 500 may fulfill a very similar functionality when compared to the current-steering stages 320, 400. However, it should be noted here that a polarity of the control signals B1, B2, B3 may, for example, be different for the current-steering transconductance stage 500 when compared to the current-steering transconductance stages 320, 400.

However, it should be noted that the current-steering transconductance stages can be modified in many ways. For example, one or more of the bipolar transistors shown in FIGS. 3, 4 and 5 may optionally be replaced by field-effect transistors, like MOSFETs or JFETs. Also, while npn transistors are shown, a complementary circuit could be used in which npn devices are replaced by pnp devices. Naturally, npn transistors could be replaced by n-channel field-effect transistors, and pnp transistors could be replaced by p-channel field-effect transistors.

Also, the amplifier could be modified, as it is known in the art. For example, one or more additional amplifying stages could be used. Also, all possible amplifier configurations, like common-emitter amplifiers, common-collector amplifiers or common-base amplifiers (or the corresponding field-effect transistor configurations) could be used. Also, a combination of multiple amplifying stages can be used in order to obtain the amplification.

In some embodiments, transistors acting as switches (for example, the transistors Q₂, Q₃, Q₄ shown in FIG. 3, or the transistors of the current-steering circuits or current-routing circuits 542, 544, 546 shown in FIG. 5) may be replaced by different types of switches, like relays, PIN diodes and so on.

As can be seen from FIGS. 3, 4 and 5, amplification and current steering/current routing can be performed in combined or separated circuit parts. For example, the variable gain amplifier 300 shown in FIG. 3 comprises a transconductance unit or transconductance stage 370, which is separated from the current-steering circuit or current-routing circuit 380.

In contrast, the functionalities of amplification and current steering/current routing are obtained by the same transistors 432, 434, 436 in the current-steering transconductance amplifier 400 shown in FIG. 4.

In the current-steering transconductance amplifier or current-steering transconductance stage 500 of FIG. 5, amplification is obtained by the amplification transistors 532, 534, 536, while the coupling between the collector terminals or drain terminals of the amplifier transistors 532, 534, 536 and the signal path of the current signals 522, 524, 526 is obtained using the current-steering circuits or current-routing circuits 542, 544, 546.

As can be seen from FIGS. 3, 4 and 5, in some embodiments a single transconductance unit 370 can be used for the generation of the current of multiple current signals. In some other embodiments, individual transconductance units (for example, individual amplifier transistors 532, 534, 536) can be used for the generation of the individual current signals (for example, of the current signals 522, 524, 526).

Configurations of the Tapped Inductor

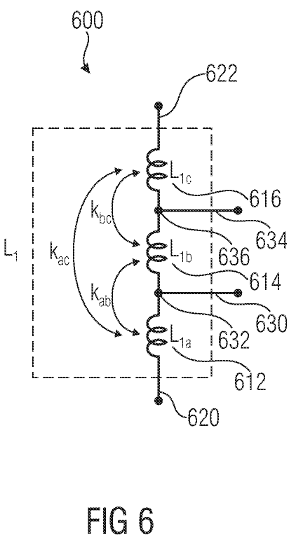

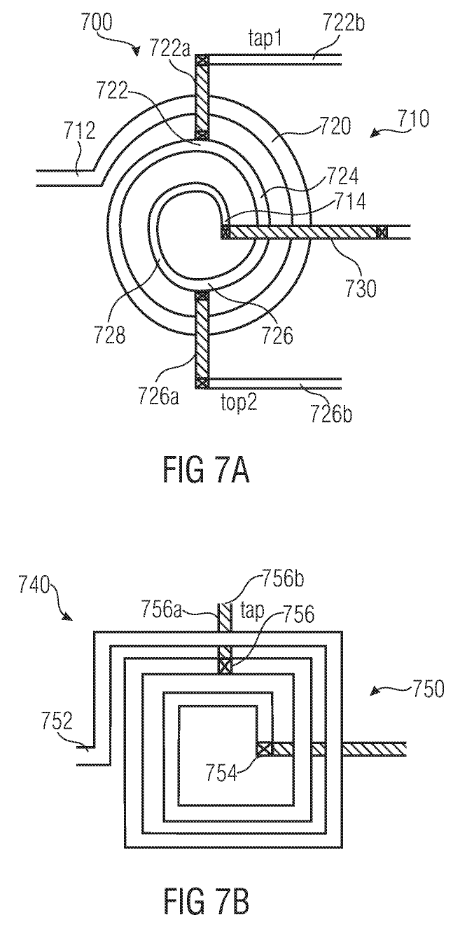

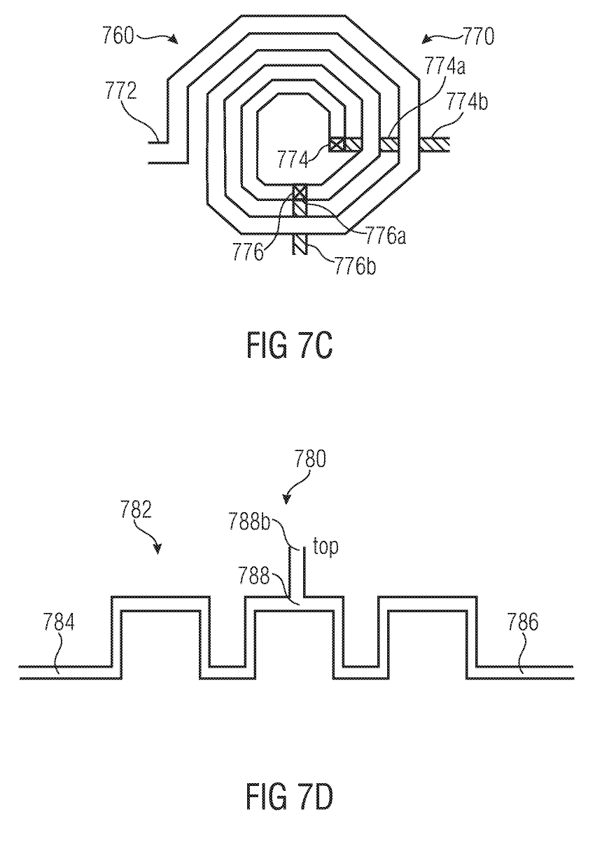

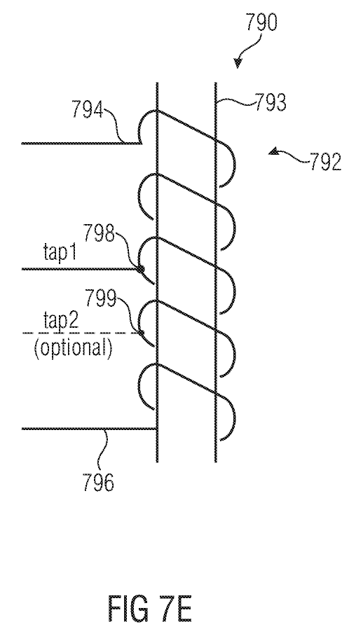

Taking reference now to FIGS. 6 and 7a to 7e, possible configurations of a tapped inductor will be described.

In some embodiments, the tapped inductor may, for example, be suited for a monolithic integration on a wafer. However, in other embodiments the inductor may be implemented as a single discrete component.

FIG. 6 shows a graphic representation of a tapped inductor, which can be used in an embodiment in accordance with an embodiment of the invention. The inductor shown in FIG. 6 is designated in its entirety with 600. Inductor 600 may, for example, replace the tapped inductor 140 shown in FIG. 1a, the tapped inductor 140a shown in FIG. 1b, the tapped inductor 240 shown in FIG. 2c or the tapped inductor 340 shown in FIG. 3.

The tapped inductor 600 may, for example, comprise a first inductive portion 612 (also designated with L₁ₐ), a second inductive portion 614 (also designated with L_{1b}) and a third inductive portion 616 (also designated with L_{1c}).

The first inductive portion 612, the second inductive portion 614 and the third inductive portion 616 may, for example, be part of a single inductive device, as will be described in more detail in the following. For example, the first inductive portion 612, the second inductive portion 614 and the third inductive portion 616 may be circuited electrically in series between a first terminal 620 at a first end of the tapped inductor 600 and a second terminal 622 at a second end of the tapped inductor 600. In other words, the terminals 620, 622 may be considered as end terminals of the tapped inductor. The tapped inductor 600 further comprises one or more taps, as will be discussed in the following. While FIG. 6 shows a tapped inductor comprising two taps, some embodiments according to the invention may comprise a tapped inductor with only a single tap. Other embodiments according to the invention may comprise a tapped inductor with more than two taps.

The tapped inductor 600 comprises a first tap 630. The first tap 630 is arranged at a node 632 between two adjacent inductive portions, for example between the first inductive portion 612 and the second inductive portion 614. In other words, the first tap 630 branches from an electrical current path between the first end terminal 620 and the second end terminal 622. However, it should be noted that in some embodiments there is no geometric discontinuity between the inductive portions 612, 614, 616. Rather, the inductive portions 612, 614, 616 may be part of a geometrically uniform conductor structure, as will also be shown with reference to FIGS. 7a to 7e.

A second tap 634 is arranged at a node 636, which is electrically arranged between the second inductive portion 614 and the third inductive portion 616. Again, in some embodiments there may be a geometrically smooth or uniform transition between the second inductive portion 614 and the third inductive portion 616. In other words, the second tap 634 may, for example, branch from a current path between the first end terminal 620 and the second end terminal 622, for example, between the second inductive portion 614 and the third inductive portion 616.

In some embodiments according to the invention, there is a magnetic coupling between at least two of the inductive portions 612, 614, 616. The magnetic coupling is illustrated in FIG. 6 by coupling coefficients k_{ab}, k_{bc}, k_{ac}. In other words, in some embodiments there may be a mutual inductance between at least two of the inductive portions 612, 614, 616. The mutual inductance may, for example, be caused by a geometry of the tapped inductor 600, which may, for example, be configured such that at least two of the inductive portions share a common magnetic flux region or magnetic flux area. In some embodiments, at least two of the inductive portions 612, 614 may even encircle a common area, such that there is a sufficient magnetic coupling between the inductive portions.

In some embodiments, a change of a current flowing through one of the inductive portions 612, 614, 616 may therefore cause an induced voltage in another of the inductive portions 612, 614, 616.

In the following, some possible implementations of a tapped inductor will be described with reference to FIGS. 7a to 7e.

FIG. 7a shows a schematic representation of a spiral inductor, which may, for example, be fabricated as a planar spiral inductor. The inductor shown in FIG. 7a is designated in its entirety with 700. The inductor 700 comprises a spiral 710, which may, for example, be fabricated using an electrically conductive material. For example, the spiral may be fabricated by structuring a conductive layer (for example, a metallization layer) in a semiconductor fabrication process or wafer processing process.

As can be seen from FIG. 7, the spiral 710 comprises, for example, an outer end or outer end terminal 712 and an inner end or inner end terminal 714.

A first inductive portion, i.e., a spiral portion 720 is arranged between the outer end 712 of the spiral 710 and a first tap node 722. In the embodiment shown in FIG. 7a, the first spiral portion or inductive portion 720 may, for example, comprise approximately 1 windings of the spiral 710. However, the first spiral portion 720 may naturally comprise more or less windings of the spiral 710. A bridge 722a may be arranged between the tap node 722 and the first tap 722b. The bridge 722a may, for example, be arranged on a different metallization layer than the spiral 720, if the spiral inductor 700 is, for example, fabricated in a semiconductor technology having a plurality of conductive layers or metallization layers.

A second spiral portion or inductive portion 724 is, for example, arranged between the first tap node 722 and a second tapped node 726. The second inductive portion or spiral portion 724 may, for example, comprise half a winding of the spiral 710. However, in some other embodiments, the second spiral portion or inductive portion 724 may naturally comprise more or less windings.

The second tap node 726 may, for example, be coupled, for example, via a bridge 726a, with a second tap 726b.

In addition, a third inductive portion or spiral portion 728 may, for example, be arranged between the second tap node 726 and the inner node of the spiral 710. Moreover, the inner end 714 of the spiral 710 may, for example, be coupled with an external connection via a bridge 730. Also, it should be noted that in the embodiment shown in FIG. 7a, the third inductive portion or third spiral portion 728 may, for example, comprise three quarters of a winding of the spiral 710.

To summarize the above, the inductive portions may be part of a single spiral in an embodiment according to the invention. Thus, a magnetic coupling between the inductive portions can easily be obtained. However, while the inductive portions 720, 724, 728 may be part of a single spiral, the impedance matching network may naturally comprise additional components, like, for example, capacitors, inductors, resistors, and so on.

However, in some embodiments, it may be sufficient if the tapped inductor comprises only a single tap.

In the following, different configurations of a planar inductor will be disclosed taking reference to FIGS. 7b and 7c.

FIG. 7b shows a schematic representation of a tapped inductor, which can be used in an embodiment according to the invention. The tapped inductor shown in FIG. 7b is designated in its entirety with 740. The tapped inductor 740 comprises a rectangular winding 750, which may, for example, comprise a plurality of rectangular or approximately quadratic windings. The winding 750 comprises an outer end 752, which may be considered as a first end or first end terminal of the tapped inductor 740. The winding 750 further comprises an inner end 754, which may be considered as a second end or second end terminal of the inductor 740. Moreover, the winding 750 comprises a tap node 756, which is arranged between the outer end 752 and the inner end 754 of the winding 750. The tap node 756 may, for example, be coupled with a tapped connection 756b via an electric conductor, which may be arranged on a different metallization layer than the winding 750. For example, the conductor 756a connecting the tapped node 756 with the tapped connection 756b may be arranged on a metallization layer, which is arranged below the winding 750, for example, if the winding 750 is fabricated in a semiconductor fabrication process.

FIG. 7c shows a schematic representation of a tapped inductor, which can be used in another embodiment according to the invention. The tapped inductor shown in FIG. 7c is designated in its entirety with 760. The tapped inductor 760 comprises an approximately octagonal winding 770. The winding 770 may, for example, comprise a plurality of turns. The approximately octagonal winding 770 comprises an outer end 772, which may also be considered as an outer end terminal. Also, the winding 770 comprises an inner end, which may be considered as an inner end terminal 774. Moreover, one or more tapped nodes 776 are arranged between the outer end 772 and the inner end 774. The tapped node 776 may be connected with a tapped connection 776b via a conducting structure 776a. Similarly, the inner end 774 of the winding 770 may be connected with an inner end connection 774b via a conductive structure 774a.

As can be seen from FIGS. 7a, 7b and 7c, there are numerous different possibilities to fabricate tapped inductors having a plurality of magnetically coupled inductive portions. Also, it can be seen from FIGS. 7a, 7b and 7c, that tapped inductors can be fabricated in a planar technology with little effort and also with high precision. For example, the position of the tap can be defined by a lithographic mask, such that the position of the tap can be adjusted with very high precision in some embodiments. Thus, the interaction between the different inductive portions, which is achieved due to the magnetic coupling, can be exploited. However, it should be noted that it is not necessary to use a spiral-type inductor. In contrast, other types of tapped inductors having a plurality of magnetically coupled portions can be used.

For example, FIG. 7d shows a schematic representation of a meander-type tapped inductor, which can also be used according to some embodiments according to the invention. The meander-type tapped inductor shown in FIG. 7d is designated in its entirety with 780. The meander-type tapped inductor comprises a meander-shaped electrically conducting structure 782. The meander-shaped electrically conducting structure may, for example, be arranged between a first end 784, which may be considered as a first end terminal, and a second end 786, which may be considered as a second end terminal. The meander-shaped electrically conducting structure 782 may, for example, comprise a tap node 788, which may, for example, be directly coupled to a tap 788b. A first inductive portion (for example, a portion of the meander-shaped electrically conducting structure 782) is arranged between the first end 784 and the tapped node 788. A second inductive portion (for example, a second portion of the meander-shaped electrically conducting structure 782) is, for example, arranged between the tap node 788 and the second end 786. Furthermore, the first inductive portion of the tapped inductor 780 may be magnetically coupled with the second inductive portion of the tapped inductor 780. For example, a magnetic field generated by a current flowing through the first inductive portion may also penetrate an area in which the second inductive portion is located. Accordingly, the magnetic field generated by the current flowing in the first inductive portion may induce a voltage in the second inductive portion. Also, a magnetic coupling in the direction may exist. In other words, a current flowing through the second magnetic portion may generate a magnetic field, which also penetrates the area in which the first inductive portion is arranged. Accordingly, a change of the current flowing in the second inductive portion may induce a voltage in the first inductive portion.

Taking reference now to FIG. 7e, an example of a non-planar tapped inductor will be described, which can also be used in an embodiment according to the invention. The tapped inductor shown in FIG. 7e is designated in its entirety with 790. The tapped inductor 790 comprises, for example, a winding 792. The winding 792 may, for example, comprise a plurality of turns. The turns of the winding 792 may, for example, be arranged around an optional magnetic core 793. However, it should be noted that the presence of a magnetic core 793 is not required. In contrast, the winding 792 may also be fabricated in the form of an air-core coil. The winding 792 may, for example, comprise a first inductive portion arranged between a first end or first end terminal 794 of the tapped inductor 790 and a first tap 798. The winding 792 may further comprise, for example, a second inductive portion arranged between the first tap 798 and a second end or second end terminal 796 of the winding 792. It should be noted that the first inductive portion and the second inductive portion may be part of a single winding 792. Alternatively, in some embodiments it may be sufficient if the first inductive portion and the second inductive portion are magnetically coupled, for example, by a magnetic core 793. For example, in some embodiments it may be sufficient if the first inductive portion and the second inductive portion are arranged on the same magnetic core 793. In other words, it is not required that the first inductive portion and the second inductive portion are part of the same winding, if a magnetic coupling between the first inductive portion and the second inductive portion is provided, for example making use of a magnetically conductive structure, like, for example, a common magnetic core.

It should be noted here that the tapped inductor 790 may naturally comprise more than one tap, if desired (for example, as indicated at reference numeral 799).

To summarize the above, different types of tapped inductors can be used in different embodiments according to the invention. In some embodiments, tapped inductors, which are fabricated in a planar technology, for example, on a semiconductor substrate, may be applied.

Method for Operating a Variable Gain Amplifier

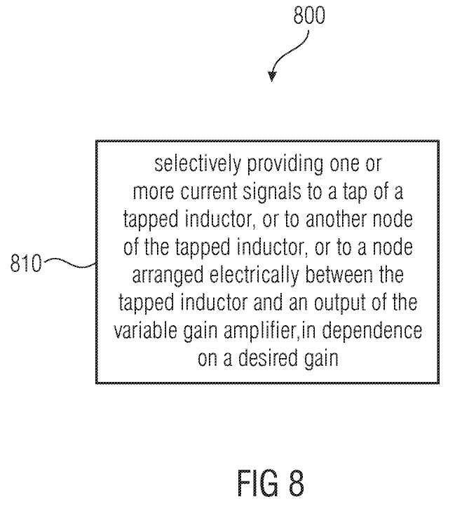

FIG. 8 shows a flowchart of a method for operating a variable gain amplifier. The method for operating the variable-gain amplifier is designated in its entirety with 800.

The method 800 may be used for operating a variable-gain amplifier, for amplifying an amplifier input signal to provide an amplifier output signal.

The method 800 comprises selectively providing 810 one or more current signals to a tap of a tapped inductor, or to another node of the tapped inductor, or to a node arranged electrically between the tapped inductor and an output of the variable gain amplifier, in dependence on a desired gain.

At least two inductive portions of the tapped inductor may be magnetically coupled, when the method 800 is performed. Also, the current signals may be dependent on the amplifier input signal. The tapped inductor may provide for an output matching of the variable-gain amplifier.

Further Aspects

To summarize the above, in some embodiments according to the invention a tapped load inductor (for example, as shown in FIG. 6) is used in the impedance transformation network of the low-noise amplifier. In some embodiments, the tapped load inductor is used in place of a simple inductor. In some embodiments, the tapped load inductor is used instead of an impedance network to scale a gain of the amplifier.

In some embodiments, the different tracks (or inductive portions) between two access nodes (for example, inductor and terminals or inductor tapped nodes, or inductor taps) of the tapped load inductor (for example, L₁ₐ, L_{1b} and L_{1c} in FIG. 6) are magnetically coupled. For example, the magnetically coupling may be indicated by coupling coefficients k_{ab}, k_{ac} and k_{bc} in FIG. 6.

An example of such a tapped load inductor, which may be used in some embodiments according to the invention, is shown in FIG. 6.

In some embodiments, one inductor end terminal and each inductor tap node (or at least one of the inductor tap nodes) may be connected to a current-steering control network, which may, for example, be configured to selectively couple a main current path of the transconductance device (for example, a collector-emitter path of a bipolar transistor, or a drain-source path of a field-effect transistor) or a main current path of a transconductance unit to the inductor end terminal or one of the inner tap nodes, according to a desired gain mode.

In some embodiments, the inductor end terminal and each of the (for example, one or more) tap nodes present, each one, a different load impedance to the transconductance stage (or to the transconductance device or to the transconductance unit), determined by the position of the tap on the inductor. Since, in some embodiments, an overall gain of the low noise amplifier may be proportional (or at least approximately proportional) to a load the transconductance stage (or transconductance device, or transconductance unit) sees, the position of the (for example, one or more) taps on the conductor may determine a value of the gain steps between the different gain modes.

In some embodiments according to the invention, an input impedance of the variable gain amplifier may be independent (or at least approximately independent) of the gain modes. For example, in some embodiments according to the invention, the transconductance stage is not altered. In some embodiments, an output impedance of the variable gain amplifier may be independent (or at least approximately independent) of the gain modes, for example, because an output impedance may only be dependent on an overall inductor value (or may be dominated by the overall inductor value).

In some embodiments according to the invention, a noise figure of the circuit may only be degraded by a small amount in low gain modes. This may, for example, be achieved since in some embodiments no signal current is thrown away.

In some embodiments according to the invention, the mechanism for setting the gain mode may not degrade (or may not significantly degrade) a maximum available gain of the amplifier in the high-gain mode, nor the linearity performance in the lower gain modes. In some embodiments according to the invention, the variable gain amplifier may be implemented without additional passive components. In some embodiments, no additional inductors, that are bulky in integrated form when compared to the rest of the circuit, are required, except for the tapped inductor. In some cases, the tapped inductor may replace an inductor which is used in conventional low-noise-amplifier circuits for the purpose of impedance matching and pull-up. In some embodiments, the magnetic coupling between the different tracks means less area to achieve a certain impedance level. Accordingly, some embodiments according to the invention are well suited for monolithic integration. According to some embodiments, the technique according to the invention is of easy implementation, since an addition of gain-steps does not disturb a tuning (for example, a matching over frequency) of the low noise amplifier, which just needs to be done for the high-gain mode.

For example, given a designed single-gain-mode low-noise-amplifier, a further gain-mode may be added by just adding a cascode transistor to the current-steering control network, and a tap to the inductor of the impedance transformation network, without further tuning. According to some embodiments, the technique can accommodate any number of gain-modes. According to some embodiments, the gain-steps can be set arbitrarily by choosing the appropriate inductor tap locations.

According to some embodiments, the technique according to the invention is robust regarding the values of the gain-steps, since the gain-steps are determined by the position of the taps on the inductor, which in turn can be implemented in a monolithic form by very precise lithography. In some embodiments, the values of the gain-steps are stable over production, since they are defined by ratios of inductances of metal lines.

In a circuit according to an embodiment of the invention, a transconductance device converts an input signal voltage into a signal current. An impedance transformation network couples the main current path of the transconductance device to the output terminal. The impedance transformation network may, for example, include one tapped inductor. A current steering circuit may include a main current path and a control terminal which receives an input signal to control a current through the main current path. The current steering circuit may selectively couple the main current path of the transconductance device to different nodes of the tapped inductor to control the amount of current provided to the output terminal, and therefore the gain of the circuit.

To summarize the above, embodiments according to the invention relate generally to gain control amplifier circuits. Some embodiments according to the invention relate to an improvement which allows attaining the same linearity performance in the lower gain modes as in the higher gain modes, without degrading the higher gain modes performance, namely the maximum available gain (MAG), while keeping a reduced dependency of the noise figure (NF) on the gain level, as well as the input and output impedances.

In some embodiments, a degradation of a noise figure with a size of gain-steps can be avoided or at least limited. Thus, an excessive increase of noise in lower gain-modes can be avoided.

According to some embodiments, a low noise amplifier is generated, which comprises an analog block connected to radio frequency (RF) inputs of an integrated circuit. The low noise amplifier comprises, for example, a tapped inductor having a relatively big size. In some embodiments, the tapped inductor may have a typical shape. In some other embodiments, the tapped inductor may be constituted by the top metallization layers.

What is claimed is:

1. A variable gain amplifier for amplifying an amplifier input signal, to provide an amplifier output signal at an amplifier output, the amplifier comprising:
a current steering transconductance stage; and
an impedance transformation network configured to match the current steering transconductance stage to the amplifier output;
wherein the impedance transformation network comprises a tapped inductor;
wherein the tapped inductor comprises a first inductive portion electrically between a first end of the tapped inductor and a tap of the tapped inductor, and a second inductive portion electrically between the tap and a second end of the tapped inductor;
wherein the first inductive portion is magnetically coupled with the second inductive portion;
wherein the current steering transconductance stage is configured to receive the amplifier input signal, to controllably provide a first current signal to a node at the first end of the tapped inductor or to a node electrically circuited between the amplifier output and the first end of the tapped inductor, and to controllably provide a second current signal to the tap of the tapped inductor;
wherein the first current signal and the second current signal are based on the amplifier input signal; and
wherein the current steering transconductance stage is configured to allow for an adjustment of a ratio of amplitudes of the first current signal and of the second current signal, to allow for an adjustment of a gain.

2. The variable gain amplifier according to claim 1, wherein the tapped inductor is electrically circuited between the amplifier output and a high-frequency ground.

3. The variable gain amplifier according to claim 1, wherein the tapped inductor is a planar inductor.

4. The variable gain amplifier according to claim 1, wherein the tapped inductor comprises a planar winding,
wherein the planar winding comprises a plurality of turns wound inside one another,
wherein the planar winding comprises the tap, and
wherein the tap is electrically arranged between an outer end of the winding and an inner end of the winding.

5. The variable gain amplifier according to claim 1, wherein the tapped inductor is monolithically integrated on a substrate together with the current steering transconductance stage.

6. The variable gain amplifier according to claim 1, wherein dimensions of the tapped inductor and a position of the tap are defined by a lithographically structured conductive layer.

7. The variable gain amplifier according to claim 1, wherein the amplifier is a high-frequency low-noise amplifier.

8. The variable gain amplifier according to claim 1, wherein the current steering transconductance stage comprises a transconductance unit and a current steering circuit;
wherein the transconductance unit is configured to provide a transconductance unit current signal at a transconductance unit output on the basis of the amplifier input signal; and
wherein the current steering circuit is configured to provide the first current signal and the second current signal by selectively coupling a signal path of the first current signal or a signal path of the second current signal with the transconductance unit output.

9. The variable gain amplifier according to claim 8, wherein the current steering circuit comprises:
a first switching element configured to selectively activate and deactivate a coupling between the transconductance unit and the signal path of the first current signal; and
a second switching element configured to selectively activate and deactivate a coupling between the transconductance unit and the signal path of the second current signal.

10. The variable gain amplifier according to claim 8, wherein the current steering circuit comprises:
a first bipolar transistor, an emitter terminal of which is coupled to the transconductance unit output, a collector terminal of which is coupled to the signal path of the first current signal, and a base terminal of which is coupled to a first control signal; or
a first field effect transistor, a source terminal of which is coupled to the transconductance unit output, a drain terminal of which is coupled to the signal path of the first current signal, and a gate terminal of which is coupled to the first control signal.

11. The variable gain amplifier according to claim 10, wherein the current steering circuit comprises:
a second bipolar transistor, an emitter terminal of which is coupled to the transconductance unit output, a collector terminal of which is coupled to the signal path of the second current signal, and a base terminal of which is coupled to a second control signal; or
a second field effect transistor, a source terminal of which is coupled to the transconductance unit output, a drain terminal of which is coupled to the signal path of the second current signal and a gate terminal of which is coupled to the second control signal.

12. The variable gain amplifier according to claim 1, wherein the current steering transconductance stage comprises a control unit configured to control the provision of the first current signal and of the second current signal,
such that the amplitude of the first current signal is larger than the amplitude of the second current signal in a first gain state, and
such that the amplitude of the second current signal is larger than the amplitude of the first current signal in a second gain state.

13. The variable gain amplifier according to claim 12, wherein the control unit is configured to control the provision of the first current signal and of the second current signal,
such that the amplitude of the first current signal exceeds the amplitude of the second current signal at least by a factor of 10 in the first gain state, and
such that the amplitude of the second current signal exceeds the amplitude of the first current signal at least by a factor of 10 in the second gain state.

14. The variable gain amplifier according to claim 1, wherein the current steering transconductance stage comprises a control circuit configured to activate the first current signal in a first gain state, and to activate the second current signal in a second gain state.

15. The variable gain amplifier according to claim 1, wherein the current steering transconductance stage comprises a control unit configured to activate both the first current signal and the second current signal in at least one gain state.

16. The variable gain amplifier according to claim 1, wherein the impedance transformation network is configured to bias at least one semiconductor device of the current steering transconductance stage via the tap of the tapped inductor.

17. The variable gain amplifier according to claim 1, wherein the current steering transconductance stage comprises a transconductance unit configured to provide a transconductance unit current signal at a transconductance unit output on the basis of the amplifier input signal,
wherein the current steering transconductance stage is configured to couple a signal path of the first current signal to the transconductance unit output in a first gain state, such that a main output current path extends from the transconductance unit output to the amplifier output, avoiding the tapped inductor, in the first gain state, and
wherein the current steering transconductance stage is configured to couple a signal path of the second current signal to the transconductance unit output in a second gain state, such that a main output current path extends from the transconductance unit output to the amplifier output via the first tap of the tapped conductor.

18. A variable gain amplifier for amplifying an amplifier input signal, to provide an amplifier output signal at an amplifier output, the amplifier comprising:
a current steering transconductance stage; and
an impedance transformation network configured to match the current steering transconductance stage to the amplifier output, the impedance transformation network comprising a tapped inductor;
wherein the tapped inductor comprises a first inductive portion electrically between a first end of the tapped inductor and a first tap of the tapped inductor, a second inductive portion electrically between the first tap of the tapped inductor and a second tap of the tapped inductor, and a third inductive portion electrically between the second tap of the tapped inductor and a second end of the tapped inductor;
wherein at least two of the inductive portions are magnetically coupled;
wherein the current steering transconductance stage is configured to receive the amplifier input signal, to controllably provide a first current signal to the first tap of the tapped inductor, and to controllably provide a second current signal to the second tap of the tapped inductor;
wherein the first current signal and the second current signal are based on the amplifier input signal; and
wherein the current steering transconductance stage is configured to allow for an adjustment of a ratio of amplitudes of the first current signal and the second current signal to allow for an adjustment of a gain.

19. The variable gain amplifier according to claim 18, wherein the tapped inductor is a planar inductor.

20. The variable gain amplifier according to claim 18, wherein the current steering transconductance stage comprises a transconductance unit and a current steering circuit;
wherein the transconductance unit is configured to provide a transconductance unit current signal at a transconductance unit output on the basis of the amplifier input signal; and
wherein the current steering transconductance stage is configured to couple a signal path of the first current signal to the transconductance unit output in a first gain state, such that a main output current path extends from the transconductance unit output to the amplifier output via the first tap of the tapped inductor, and
wherein the current steering transconductance stage is configured to couple a signal path of the second current signal to the transconductance unit output in a second gain state, such that a main output current path extends from the transconductance unit output to the amplifier output via the second tap of the tapped conductor.

21. A variable gain amplifier for amplifying an amplifier input signal, to provide an amplifier output signal at an amplifier output, the amplifier comprising:
a current steering transconductance stage; and
an impedance transformation network configured to match the current steering transconductance stage to the amplifier output, the impedance transformation network comprising a tapped inductor;
wherein the tapped inductor comprises a first inductive portion electrically between a first end of the tapped inductor and a first tap of the tapped inductor, a second inductive portion electrically between the first tap of the tapped inductor and a second tap of the tapped inductor, and a third inductive portion electrically between the second tap of the tapped inductor and a second end of the tapped inductor,
wherein at least two of the inductive portions are magnetically coupled;
wherein the current steering transconductance stage is configured to receive the amplifier input signal, to controllably provide a first current signal to a node at the first end of the tapped inductor or to a node electrically circuited between the amplifier output and the first end of the tapped inductor, to controllably provide a second current signal to the first tap of the tapped inductor, and to controllably provide a third current signal to the second tap of the tapped inductor;
wherein the first current signal, the second current signal and the third current signal are based on the amplifier input signal;
wherein the current steering transconductance stage is configured to allow for an adjustment of a ratio of amplitudes of the first, second and third current signals, to allow for an adjustment of a gain of the variable-gain amplifier;
wherein the tapped inductor comprises a planar winding, the planar winding comprising a plurality of turns wound inside one another;
wherein the planar winding comprises the first tap of the tapped inductor and a second tap of the tapped inductor;
wherein the first tap of the tapped inductor is electrically arranged between an outer end of the planar winding and an inner end of the planar winding; and
wherein the second tap of the tapped inductor is electrically arranged between the outer end of the planar winding and the inner end of the planar winding.

22. The variable gain amplifier according to claim 21, wherein the tapped inductor is monolithically integrated on a substrate together with the current steering transconductance stage.

23. The variable gain amplifier according to claim 21, wherein dimensions of the tapped inductor and a position of the tap are defined by a lithographically structured metal layer.

24. The variable gain amplifier according to claim 21, wherein the current steering transconductance stage comprises a transconductance unit configured to provide a transconductance unit current signal at a transconductance unit output on the basis of the amplifier input signal, and
wherein the current steering transconductance stage is configured to couple a signal path of the first current signal to the transconductance unit output in a first gain state, such that a main output current path extends from the transconductance unit output to the amplifier output, avoiding the tapped inductor, in the first gain state,
wherein the current steering transconductance stage is configured to couple a signal path of the second current signal to the transconductance unit output in a second gain state, such that a main output current path extends from the transconductance unit output to the amplifier output via the first tap of the tapped conductor, and
wherein the current steering transconductance stage is configured to couple a signal path of the third current signal to the transconductance unit output in a third gain state, such that a main output current path extends from the transconductance unit output to the amplifier output via the second tap of the tapped conductor.

25. A variable gain amplifier for amplifying an amplifier input signal, the amplifier comprising:
a current steering transconductance stage comprising a transconductance device,
the transconductance device being configured to control a current flowing via a main current path of the transconductance device in dependence on the amplifier input signal;
an impedance transformation network configured to match an impedance of the transconductance stage to an output impedance of the variable gain amplifier;
wherein the impedance transformation network comprises a tapped inductor,
wherein the tapped inductor comprises a first inductive portion electrically between a first end of the tap inductor and a tap of the tapped inductor, and a second inductive portion electrically between the tap and a second end of the tapped inductor;
wherein the first inductive portion is magnetically coupled with the second inductive portion; and
wherein the current steering transconductance stage is configured to selectively couple the main current path of the transconductance device to the tap or to another node of the tapped inductor, to allow for a control of a gain of the variable gain amplifier.

26. The variable gain amplifier according to claim 25, wherein the other node of the tapped inductor is an end of the tapped inductor or a second tap of the tapped inductor.

27. A method for operating a variable-gain amplifier, for amplifying an amplifier input signal to provide an amplifier output signal, the method comprising:
selectively providing one or more current signals to a tap of a tapped inductor, or to another node of the tapped inductor, or to a node arranged electrically between the tapped inductor and an output of the variable gain amplifier, in dependence on a desired gain,
wherein at least two inductive portions of the tapped inductor are magnetically coupled;
wherein the current signals are dependent on the amplifier input signal; and
wherein the tapped inductor provides for an output matching of the variable-gain amplifier.
